(19) United States
(12) Patent Application Publication
(10) Pub. No.: US 2018/0054918 A1
(43) Pub. Date: Feb. 22, 2018

(54) PROACTIVE FAN SPEED ADJUSTMENT

(71) Applicant: Futurewei Technologies, Inc., Plano, TX (US)

(72) Inventor: Zhiyuan Wang, Fremont, CA (US)

(21) Appl. No.: 15/674,773

(22) Filed: Aug. 11, 2017

Related U.S. Application Data
(60) Provisional application No. 62/376,572, filed on Aug. 18, 2016.

(51) Int. Cl. H05K 7/20; H05K 1/02

(52) U.S. Cl. CPC H05K 7/20209; H05K 7/20136; H05K 1/0203

(57) ABSTRACT

Disclosed herein are various embodiments of a system and method for proactively adjusting a fan speed of an electronic device to inhibit an expected increase in temperature of the electronic device based on a current measurement of one or more electrical components of the electronic device.

### CROSS-REFERENCE TO RELATED APPLICATIONS

This application claims priority to U.S. Provisional Patent Application No. 62/376,572 filed Aug. 18, 2016 by Zhiyuan Wang and titled “Proactive Fan Speed Adjustment,” which is incorporated by reference.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Components within electronic devices produce heat as they are being used. For example, components that are susceptible to temporary malfunction or permanent failure if overheated include integrated circuits such as a processor, chipset, graphics cards, and hard disk drives. Thus, cooling is required to remove the waste heat produced by computer components, to keep components within permissible operating temperature limits. One method of cooling is the use of fans that react to changes in temperature. For instance, as the temperature inside an electronic device increases, the fan is configured to react to the rise in temperature and adjust its speed to exhaust hot air in order to reduce the ambient temperature within the electronic device.

### SUMMARY

According to one aspect of the present disclosure, there is provided a device that includes a circuit board having at least one electrical component thereon. The device further includes a fan configured to generate an airflow over the at least one electrical component in order to dissipate heat, a current sensor configured to measure a current through the at least one electrical component to determine a sensed current, and a processor configured to execute instructions to proactively adjust a speed of the fan based on a predetermined temperature change expected for the sensed current.

According to a second aspect of the present disclosure, there is provided a method of proactive fan speed adjustment implemented by a device. In one embodiment, the method includes the step of retrieving a prediction table that includes data indicating an expected temperature increase for at least one electrical component on a circuit board of the device. The method monitors a current through the at least one electrical component and calculates a power based on the sensed current. The method determines the expected temperature increase for the at least one electrical component based on power calculated using the prediction table. The method proactively adjusts a fan speed based on the expected temperature to inhibit the at least one electrical component from reaching the expected temperature.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a block diagram illustrating an electronic device comprising electrical components cooled by a fan based on a sensed temperature in accordance with an embodiment of the disclosure;

FIG. 2 is a chart illustrating fan speed adjustment in accordance with an embodiment of the disclosure;

FIG. 3 is a block diagram illustrating a device comprising electrical components cooled by a fan based on a measured current and an expected temperature rise in accordance with an embodiment of the disclosure;

FIG. 4 is a chart illustrating a prediction table in accordance with an embodiment of the disclosure;

FIG. 5 is a graph illustrating a comparison between fan speed adjustment techniques in accordance with an embodiment of the disclosure;

FIG. 6 is a flowchart illustrating a method for performing predictive fan speed adjustment in accordance with an embodiment of the disclosure.

### DETAILED DESCRIPTION

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

Disclosed herein is a method and system for proactively adjusting a fan speed based on a current measurement and a predicted temperature change (i.e., increase or decrease) in order to maintain electronic components on a circuit board within a device at a stable temperature. The disclosed embodiments improve upon existing systems and methods that only react to temperature changes instead of proactively adjusting to a predicted temperature change. By doing so, the lifespan of the electrical components is improved.

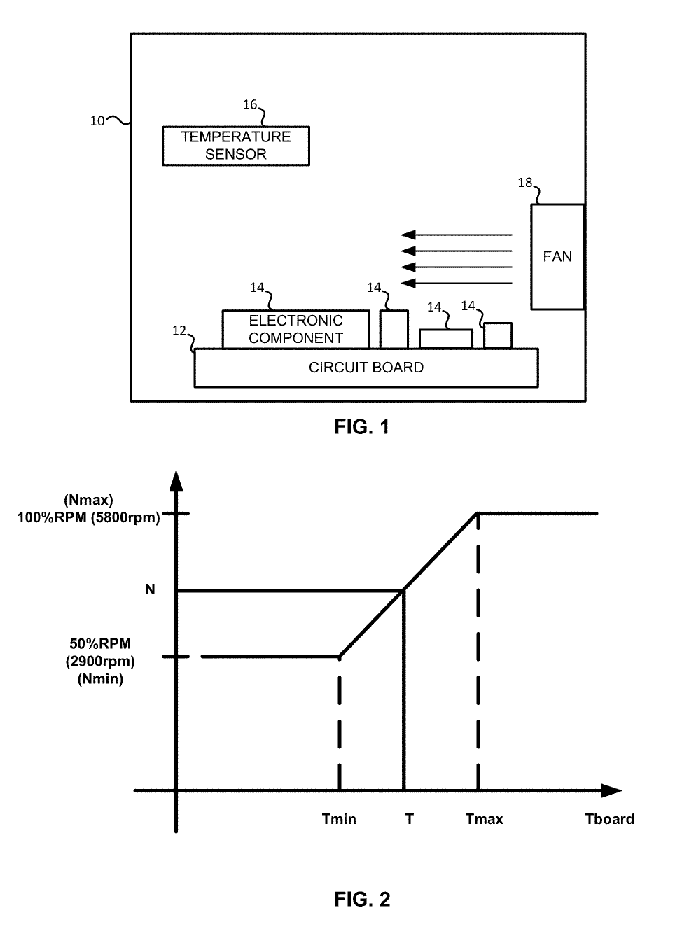

FIG. 1 illustrates an example of an electronic device 10 (e.g., communications device, laptop computer, etc.) in accordance with an embodiment of the disclosure. The electronic device 10 includes a circuit board 12 having a variety of electrical components 14 (e.g., integrated circuits, chips, electronic components, etc.) thereon. When in use, the electrical components 14 generate heat. This causes the temperature of the electrical components 14 and/or the temperature within the electronic device 10, as measured by a temperature sensor 16, to rise. If the electrical components 14 get too hot, they are likely to malfunction or fail.

In order to try and keep the electrical components 14 cool, the electronic device 10 includes a fan 18. The fan 18 moves air across the electrical components 14 (as shown by the arrows) to dissipate the heat generated by the electrical components 14.

FIG. 2 is a chart illustrating fan speed adjustment in accordance with a conventional electronic device such as electronic device 10. As depicted in the chart, the speed of the fan 18 may be adjusted based on the temperature of the circuit board 12 (Tboard) sensed by the temperature sensor 16. For example, if the temperature sensor 16 senses a minimum temperature (Tmin), the speed of the fan 18 may be set to a minimum speed (Nmin) of, for example, 2900 revolutions per minute (rpm) or fifty percent (50%) of the fan's maximum speed. If the temperature sensor 16 senses a maximum temperature (Tmax), the speed of the fan 18 may be set to a maximum speed (Nmax) of, for example, 5800 rpms or 100% of the fan's maximum speed. If the temperature sensor 16 senses an operating temperature (T) between Tmin and Tmax, the speed of the fan 18 may be set to a corresponding speed (N). As shown, the fan's speed increases linearly relative to the sensed temperature.

As shown above, the fan speed adjustment technique is based on the temperature of the components as sensed by the temperature sensor 16. As the sensed temperature increases, the fan speed is increased in response. Therefore, the approach used by conventional devices is reactive, i.e., measure a temperature and then increase fan speed accordingly thereafter. Thus, fan speed adjustment lags behind the sensed temperature. In addition, the location of the sensor may impact or affect the fan speed adjustment.

Disclosed herein is a proactive fan speed adjustment technique. As will be more fully explained below, instead of reactively adjusting fan speed based on a measured temperature, the fan speed is proactively measured based on a sensed current and an expected temperature increase relative to the sensed current.

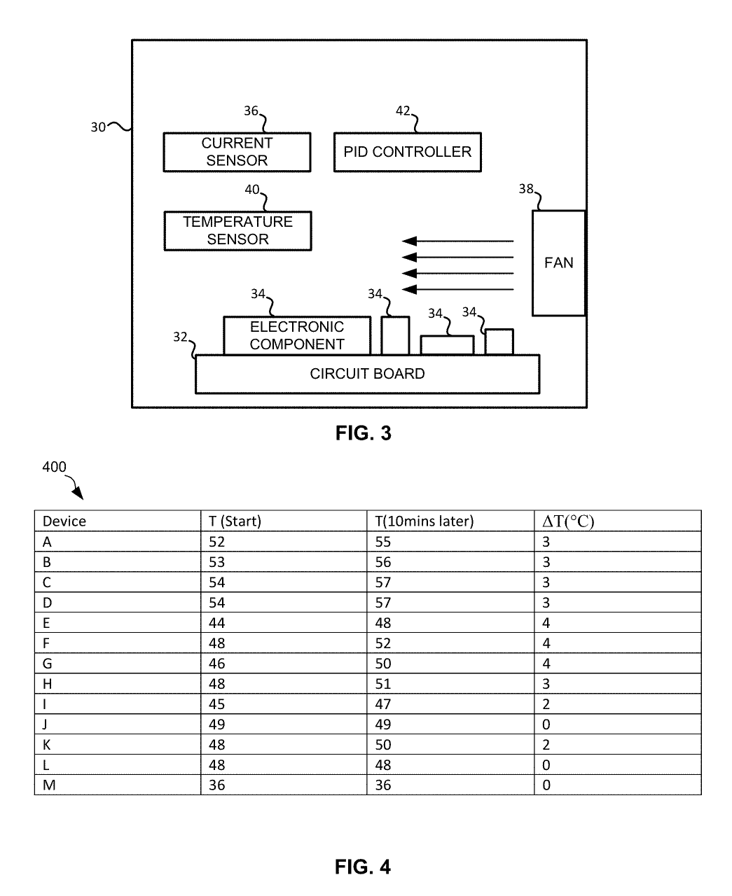

FIG. 3 illustrates an embodiment of an electronic device 30 (e.g., a mobile communications device, laptop computer, etc.) benefitting from the proactive fan speed adjustment technique in accordance with an embodiment of the disclosure. The electronic device 30 includes a circuit board 32 having a variety of electrical components 34 (e.g., integrated circuits, a processor, memory, etc.) thereon. When in use, the electrical components 34 generate heat. This causes the temperature of the electrical components 34 and/or the temperature within the electronic device 30 to rise. If the electrical components 34 get too hot, they are likely to malfunction or fail.

Similar to electronic device 10, in order to keep the electrical components 34 cool, the electronic device 30 includes a fan 38. The fan 38 moves air across the electrical components 34 (as shown by the arrows) to dissipate the heat generated by the electrical components 34. The electronic device 30 may also include one or more openings to alleviate the heat generated by the electrical components 34.

However, instead of the fan's speed being adjusted based on a sensed temperature as configured in conventional electronic devices, the fan's speed is proactively adjusted based on a sensed current and an expected or predicted temperature increase relative to the sensed current in accordance with the disclosed embodiments. For example, in one embodiment, the electronic device 30 includes a current sensor 36 configured to measure a current through one or more of the electrical components 34 and/or the circuit board 32. In an embodiment, the electronic device 30 may also include a temperature sensor 40 used to measure the temperature of the electrical components 34 and/or the temperature within the electronic device 30. The current sensor 36 and the temperature sensor 40 may be positioned at any location within the electronic device 30.

In certain embodiments, the electronic device 30 may include more than one current sensor 36, temperature sensor 40, or fan 38. Thus, in some embodiments, the temperature of the electrical components 34 may be proactively controlled by adjusting more than one fan 38 within the electronic device 30 using the process described herein. Further, the proactive adjustment to each of the fans may be different. For example, in some embodiments, based on location of a particular fan, the timing (i.e., when the fan speed is adjusted) and the speed of the adjustment of each fan may differ.

In accordance with an embodiment of the disclosure, the fan 38 is proactively adjusted by including a “prediction” component to a proportional-integral-derivative (PID) formula used by, for example, a PID controller 42 within the electronic device 30 to adjust the speed of the fan 38. One such PID formula with a prediction component is shown below:

fan_speed(t)=Kₚ*e(t)+Kᵢ*∫e(t)dt+K_{d}*d(e(t))/dt+Prediction

Where Kp, Ki, and Kd are all non-negative and denote the coefficients for the proportional, integral, and derivative terms, respectively (denoted P, I, and D). In one embodiment, the prediction component is based on traffic volume through the device, the power consumption of the device, and a current measurement for the device as more fully explained below.

When the traffic volume (e.g., voice or data traffic) through the electronic device 30 is increased (e.g., from 0% to 50% or 100%), the current through the electronic device 30 also increases (e.g., from 1 ampere (amp) to 5 amps). The rise in current correlates to a rise in the power used (current×voltage=power). The increase in power causes a change in temperature for electrical components 34 within the electronic device 30 (e.g., between 0° C. and 4° C.) after a period of time (e.g., from 2 minutes to 10 minutes). Thus, in accordance with an embodiment of the disclosure, when an increase in current through the electronic device 30 is experienced, the speed of the fan 38 is increased to prevent or inhibit a rise in the temperature. Accordingly, the fan speed is adjusted proactively before a significant or undesirable rise in temperature is ever experienced.

FIG. 4 illustrates an example of a prediction table 400 that may be used to implement the prediction technique in accordance with an embodiment of the disclosure. Prediction table 400 may be stored in a device memory. As shown, the prediction table 400 includes a column labeled “Device” that lists electrical components found on the circuit board within the device, a column labeled “T (Start)” that lists the starting temperature of each of the electrical components, a column labeled “T (10 min later)” that lists the temperature of each of the electrical components at a later time (which could also be 2 minutes, 3 minutes, etc.), and a column labeled “ΔT (° C.)” that lists the change in temperature of each of the electrical components from the starting temperature to the later temperature. In the depicted embodiment, the prediction table 400 is generated based on a change in temperature when the traffic volume (e.g., the bandwidth, data rate, etc.) increases from 0 to 50%, thus increasing the power used by the electronic device 30 from 557 watts (W) to 644 W. As shown in FIG. 4, the change in traffic volume/power consumption results in a temperature change of between 0 and 4 degrees Celsius (° C.) for each component. This expected or predicted temperature change is then utilized to proactively adjust the fan speed based on current measurements.

As an example, when the traffic volume increases to 50% and the measured power (as a function of current and voltage) increases to 644 W, the electronic device 30 determines, based on the prediction table 400, that the temperature of the electrical components 34 is likely to rise between 0 and 4° C. However, before the temperature rise is experienced by the electronic device 30, the fan speed is increased to prevent that occurrence. In certain embodiments, the fan speed may be increased by 10%, 20%, etc., to inhibit or prevent a significant or detrimental temperature increase from ever happening. Moreover, this proactive adjustment of the fan speed is done without having to sense a temperature in the device and/or reacting to that sensed temperature. Instead, the electronic device 30 deals with the predicted or expected temperature change before it occurs based on the prediction table 400. It should be noted that the disclosed embodiment is not limited by the data in the prediction table 400 as different board designs/devices will have different predicted temperature changes. However, the proactive process disclosed herein may be applied to all types of electronic devices.

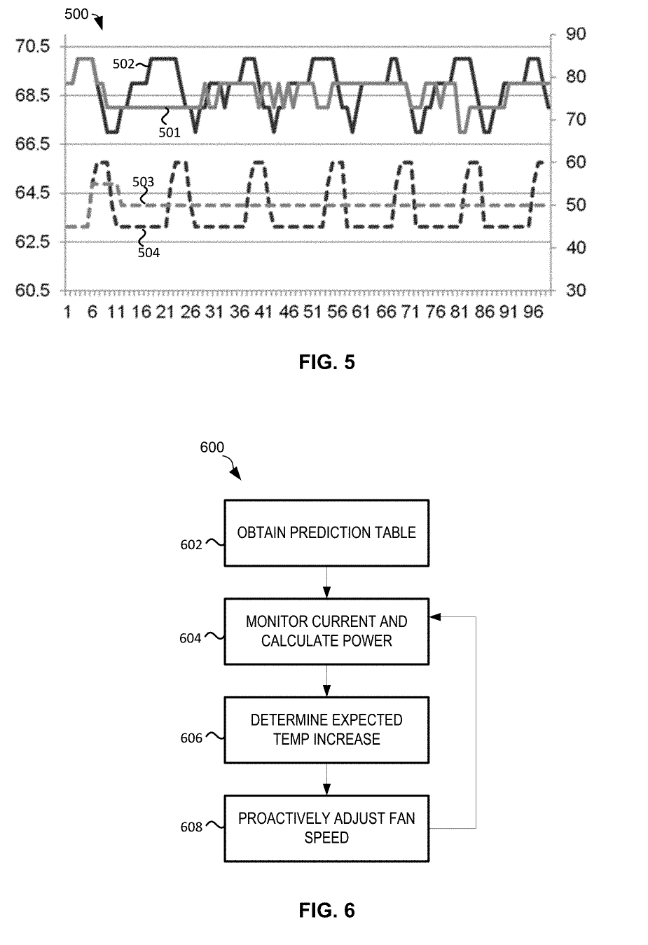

FIG. 5 is a graph 500 illustrating the benefit of proactively adjusting fan speed versus reactively adjusting fan speed in accordance with an embodiment of the disclosure. The graph 500 depicts the device temperature in degrees Celsius (° C.) along the left axis, time in sample points (e.g., one sample every 20 seconds) on the bottom axis, and the fan speed percentage along the right axis. The top pair of lines illustrates the device temperature. The lighter line 501 is the temperature of a device using the proactive temperature measurement technique in accordance with an embodiment of the disclosure, while the darker line 502 is the temperature of the device using a reactive technique as in conventional devices. As shown, peaks in temperature in the lighter line 501 are less severe than those in the darker line 502. Thus, the temperature of the device under observation was kept more stable using the proactive temperature measurement technique.

The bottom pair of lines illustrates the fan speed. The lighter line 503 is the fan speed using the proactive temperature measurement technique in accordance with an embodiment of the disclosure, while the darker line 504 is the fan speed using the conventional reactive technique. As shown, the fan speed was more consistent using the proactive technique. In addition, the fan speed increased more quickly for the proactive technique between about time 5 to about time 6 than the fan speed increased for that same period using the reactive technique. In other words, the lighter line 503 has a greater slope than the darker line 504 between about time 5 and time 6.

FIG. 6 is a method 600 of predictive fan speed adjustment in accordance with an embodiment of the disclosure. The method 600 may be implemented by an electronic device such as, but not limited to, electronic device 30. The method 600 may be implemented when an increase in current (which corresponds to power) is observed within the electronic device (i.e., through one or more of the electrical components). The method 600 begins at step 602 by storing or retrieving a prediction table that comprises data indicating a predicted rise in temperature based on current flow measured through one or more components of an electronic device.

The method 600 at step 604 monitors a current flow through one or more electrical components and calculates a corresponding power based on the current measurement. The method 600 at step 606 determines the expected temperature increase for the electrical component based on the calculated power using the prediction table. At step 608, the method 600 proactively adjusts the fan speed based on the expected temperature to inhibit the electrical component from reaching the expected temperature. The method 600 repeats at step 604 to continually monitor and proactively adjust the fan speed as needed.

As shown above, the disclosed embodiments provide numerous benefits. For example, the temperature of the electrical components in the device is kept more stable relative to known techniques of cooling. Therefore, the lifespan of the electrical components is improved and device failure is less likely. In addition, the fan speed may be more stable and lower, which produces less noise.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A device, comprising:
a circuit board comprising at least one electrical component;
a fan configured to generate an airflow over the at least one electrical component in order to dissipate heat;
a current sensor configured to measure a current through the at least one electrical component to determine a sensed current; and
a processor configured to execute instructions to proactively adjust a speed of the fan based on a predetermined temperature change expected for the sensed current.

2. The device of claim 1, wherein the speed of the fan is not adjusted solely based on a temperature sensed within the device.

3. The device of claim 1, wherein the speed of the fan is not adjusted solely based on a temperature of the at least one electrical component.

4. The device of claim 1, wherein the sensed current is used to determine a device power, wherein the device power is used to proactively adjust the speed of the fan.

5. The device of claim 1, wherein the electrical component is an integrated circuit.

6. The device of claim 1, wherein the predetermined temperature change is stored in a prediction table stored in a memory of the device.

7. The device of claim 1, further comprising a fan controller receiving the sensed current and controlling the fan, wherein the sensed current and the predetermined temperature change expected for the sensed current are used to proactively adjust the speed of the fan.

8. A device, comprising:
a memory storing a prediction table;
a circuit board bearing at least one electrical component;
a fan configured to generate an airflow over the at least one electrical component in order to dissipate heat;
a current sensor configured to determine a sensed current through at least one electrical component of the circuit board; and
a processor configured to execute instructions to determine a predetermined temperature change based on the sensed current and data from the prediction table, and proactively adjust a speed of the fan based the predetermined temperature change.

9. The device of claim 8, wherein the device further comprises a temperature sensor, and wherein the speed of the fan is not adjusted solely based on a temperature sensed within the device.

10. The device of claim 8, wherein the sensed current is used to determine a device power, wherein the device power is used to proactively adjust the speed of the fan.

11. The device of claim 8, wherein the electrical component is an integrated circuit.

12. A method of proactive fan speed adjustment implemented by a device, comprising:
retrieving a prediction table, wherein the prediction table includes an expected temperature increase for at least one electrical component on a circuit board of the device;
monitoring a current through the at least one electrical component and calculating a power based on the sensed current;
determining the expected temperature increase for the at least one electrical component based on power calculated using the prediction table; and
proactively adjusting a fan speed based on the expected temperature to inhibit the at least one electrical component from reaching the expected temperature.

13. The method of claim 12, wherein the expected temperature increase in the prediction table is based on an increase in power observed when traffic volume through the device is increased.

14. The method of claim 12, wherein the traffic volume corresponds to a data rate.

15. The method of claim 12, wherein the traffic volume corresponds to bandwidth.

16. The method of claim 12, wherein the prediction table includes a temperature of the at least one electrical component at a start time, a temperature of the at least one electrical component at a later time, and a change in temperature between the start time and the later time.

17. The method of claim 16, wherein the later time is between one to three minutes after the start time.

18. The method of claim 12, wherein proactively adjusting the fan speed based on the expected temperature is performed by including a prediction component in a proportional-integral-derivative (PID) formula.

19. The method of claim 12, wherein proactively adjusting the fan speed permits non-linear fan speed adjustments over time.

20. The method of claim 12, wherein proactively adjusting the fan speed comprises proactively adjusting speeds of more than one fan in the device.
